(19) United States
(12) Patent Application Publication
(10) Pub. No.: US 2024/0081121 A1
(43) Pub. Date: Mar. 7, 2024

(54) DISPLAY DEVICE

(71) Applicant: Samsung Display Co., Ltd., Yongin-si (KR)

(72) Inventors: Yeongho Lee, Yongin-si (KR); Chanyoung Kim, Yongin-si (KR); Junhee Lee, Yongin-si (KR); Choongyoul Im, Yongin-si (KR); Seongyong Hwang, Yongin-si (KR)

(73) Assignee: Samsung Display Co., Ltd., Yongin-si (KR)

(21) Appl. No.: 18/329,789

(22) Filed: Jun. 6, 2023

(30) Foreign Application Priority Data
Sep. 7, 2022 (KR) 10-2022-0113789

(51) Int. Cl. H10K 59/38; G09G 3/3233; H10K 59/122; H10K 59/40; H10K 59/80

(52) U.S. Cl. CPC H10K 59/38; G09G 3/3233; H10K 59/122; H10K 59/40; H10K 59/873; H10K 59/8792; G09G 2300/0842

(57) ABSTRACT

A display device includes a plurality of pixel electrodes disposed on a substrate, an emission layer disposed on each of the plurality of pixel electrodes, a counter electrode disposed on the emission layer to correspond to the plurality of pixel electrodes, an insulating layer disposed on the counter electrode and including a trench corresponding to an area between the plurality of pixel electrodes, a light blocking material layer disposed in the trench, and a color filter layer disposed on the insulating layer and selectively transmitting light of a specific wavelength band.

### CROSS-REFERENCE TO RELATED APPLICATION(S)

This application claims priority to and benefits of Korean Patent Application No. 10-2022-0113789 under 35 U.S.C. § 119, filed on Sep. 7, 2022 in the Korean Intellectual Property Office, the entire contents of which are herein incorporated by reference.

### BACKGROUND

### 1. Technical Field

One or more embodiments relate to a display device in which the scattering reflection of external light by a color filter may be reduced.

### 2. Description of the Related Art

Display devices display images by receiving information about the images. A color filter included in a display device may have an edge that protrudes upward by a light blocking material layer (black matrix) located below the edge, and an upper surface of the color filter may be a curved surface having a certain curvature. The above shape of the color filter may cause scattering reflection of external light so that the image quality of the display device is degraded.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

One or more embodiments include a display device in which the scattering reflection of external light by a color filter is reduced. However, such an aspect is just an example, and the scope of the disclosure is not limited thereby.

Additional aspects will be set forth in part in the description which follows and, in part, will be apparent from the description, or may be learned by practice of the embodiments of the disclosure.

According to one or more embodiments, a display device may include a plurality of pixel electrodes disposed on a substrate, an emission layer disposed on each of the plurality of pixel electrodes, a counter electrode disposed on the emission layer to correspond to the plurality of pixel electrodes, an insulating layer disposed on the counter electrode and including a trench corresponding to an area between the plurality of pixel electrodes, a light blocking material layer disposed in the trench, and a color filter layer disposed on the insulating layer and selectively transmitting light of a specific wavelength band.

A thickness of the light blocking material layer and a depth of the trench may be same.

An upper surface outside the trench and an upper surface of the light blocking material layer may form a continuous surface.

The display device may further include a thin film encapsulation layer disposed between the counter electrode and the insulating layer, and including a first inorganic encapsulation layer, a second inorganic encapsulation layer disposed on the first inorganic encapsulation layer, and an organic encapsulation layer disposed between the first inorganic encapsulation layer and the second inorganic encapsulation layer. The second inorganic encapsulation layer and the insulating layer may include a same material

The thickness of the insulating layer may be greater than the thickness of the second inorganic encapsulation layer.

The depth of the trench may be greater than the thickness of the second inorganic encapsulation layer.

The display device may further include a first metal electrode disposed on the second inorganic encapsulation layer and covered by the insulating layer. A second metal electrode disposed on a lower surface of the trench to be disposed in the trench, and connected to the second metal electrode via a through-hole formed in the insulating layer.

The light blocking material layer may cover the second metal electrode.

The depth of the trench may be about 1.4 μm or more and about 1.5 μm or less.

The color filter layer may include a first color filter layer that transmits light of a first wavelength band. When viewed from a direction perpendicular to the substrate, the area of the first pixel opening may be less than the area of the first color filter layer.

The light blocking material layer may be disposed adjacent to an edge of the first color filter layer.

The display device may further include a pixel defining layer disposed on the substrate and including a plurality of pixel openings that expose a central portion of each of the plurality of pixel electrodes disposed on the substrate, and a spacer disposed on the pixel defining layer.

When viewed from a direction perpendicular to the substrate, the spacer may be disposed in the trench.

When viewed from a direction perpendicular to the substrate, the trench may overlap the pixel defining layer.

When viewed from a direction perpendicular to the substrate, the width of the trench may be less than a distance between the pixel openings.

According to one or more embodiments, a display device may include a plurality of pixel electrodes disposed on a substrate, an emission layer disposed on each of the plurality of pixel electrodes, a counter electrode disposed on the emission layer to correspond to the plurality of pixel electrodes, an insulating layer disposed on the counter electrode and including a trench corresponding to an area between the plurality of pixel electrodes, and a first color filter layer disposed on the insulating layer and transmitting light of a first wavelength band, an edge of the first color filter layer being located in the trench.

The display device may further include a second color filter layer disposed on the insulating layer to be adjacent to the first color filter layer, transmitting light of a second wavelength band that is different from the first wavelength band, and including an edge disposed in the trench.

The display device may further include a light blocking material layer disposed on an interface where the edge of the first color filter layer meets an edge of the second color filter layer.

The display device may further include a third color filter layer disposed on the insulating layer to be adjacent to the first color filter layer, transmitting light of a third wavelength band that is different from the first wavelength band and the second wavelength band, and including an edge disposed in the trench.

The light blocking material layer may be disposed on an interface where the edge of the first color filter layer meets an edge of the third color filter layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display device according to an embodiment;

FIG. 2 is a schematic equivalent circuit diagram of a pixel of the display device of FIG. 1;

FIG. 3 is a schematic cross-sectional view of a part of the display device of FIG. 1;

FIG. 4 is a schematic cross-sectional view of a part of the display device of FIG. 1;

FIG. 5 is a schematic cross-sectional view of the vicinity of a color filter layer of the display device of FIG. 1;

FIG. 6 is a schematic cross-sectional view of the vicinity of a color filter layer of a display device according to an embodiment;

FIG. 7 is a schematic cross-sectional view of the vicinity of a color filter layer of a display device according to an embodiment; and

FIG. 8 is a schematic cross-sectional view of the vicinity of a color filter layer of a display device according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean any combination including “A, B, or A and B.”

When a component, such as a layer, a film, a region, or a plate, is referred to as being “on” another component, the component can be directly on the other component or intervening components may be present thereon. Furthermore, sizes of components in the drawings may be exaggerated for convenience of explanation. For example, since sizes and thicknesses of components in the drawings may be arbitrarily illustrated for convenience of explanation, the following embodiments are not limited thereto.

In the following embodiment, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

It will be understood that the terms “connected to” or “coupled to” may include a physical or electrical connection or coupling.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

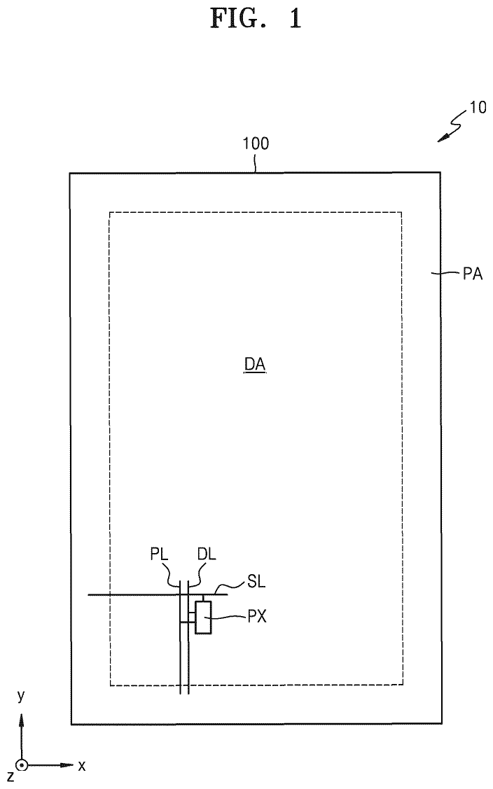

FIG. 1 is a schematic plan view of a display device according to an embodiment.

As illustrated in FIG. 1, a display device according to an embodiment may include a display panel 10. The display device may be any device including the display panel 10. For example, the display device may be one of various devices, such as a smartphone, a tablet personal computer, a laptop computer, a television, a billboard, or the like. The display device according to an embodiment may include thin film transistors, a capacitor, and the like, and the thin film transistors, the capacitor, or the like may be implemented by conductive layers and insulating layers.

The display panel 10 may include a display area DA and a peripheral area PA arranged outside the display area DA. FIG. 1 illustrates that the display area DA has a rectangular shape. However, the disclosure is not limited thereto. The display area DA may have various shapes, such as a circular shape, an oval shape, a polygonal shape, a shape of a specific figure, or the like.

The display area DA may be a portion for displaying an image, in which multiple pixels PX may be arranged. Each pixel PX may include a display element such as an organic light-emitting diode. Each pixel PX may emit, for example, red, green, or blue light. Each pixel PX may be connected to a pixel circuit including a thin film transistor (TFT), a storage capacitor, and the like. The pixel circuit may be connected to a scan line SL configured to transmit a scan signal, a data line DL crossing the scan line SL and configured to transmit a data signal, a driving voltage line PL configured to supply a driving voltage, and the like. The scan line SL may extend in an x direction (hereinafter, a second direction), and the data line DL and the driving voltage line PL may extend in a y direction (hereinafter, a first direction).

Each pixel PX may emit light having a luminance corresponding to an electrical signal from the pixel circuit to which the pixel PX is electrically connected. The display area DA may display a certain image through light emitted from each pixel PX. For reference, each pixel PX may be defined as a light-emitting area that emits light of any one color of red, green, and blue, as described above.

The peripheral area PA, in which the pixel PX is not arranged, may be an area that does not display an image. A power supply wiring for driving each pixel PX, and the like, may be arranged in the peripheral area PA. Furthermore, multiple pads may be arranged in the peripheral area PA, and a printed circuit board including a driving circuit portion or an integrated circuit element such as a driver IC may be arranged in and electrically connected to the pads.

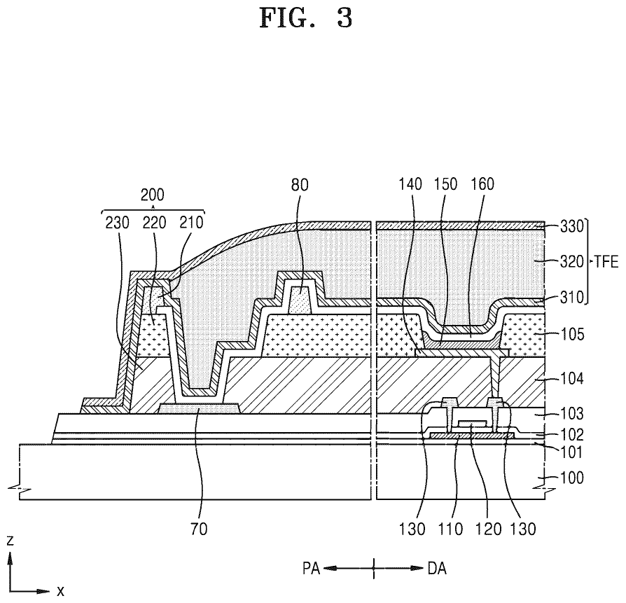

For reference, as the display panel 10 includes a substrate 100 (see FIG. 3), it may be said that the substrate 100 includes the display area DA and the peripheral area PA. The substrate 100 is described below in detail.

Furthermore, multiple transistors may be arranged in the display area DA. According to the type (N-type or P-type) of a transistor and/or the operation conditions, a first terminal of a transistor may be a source terminal or a drain terminal, and a second terminal thereof may be a terminal different from the first terminal. For example, in case that the first terminal is a source terminal, the second terminal may be a drain terminal.

The transistors may include a driving transistor, a data write transistor, a compensation transistor, an initialization transistor, an emission control transistor, and the like. The driving transistor may be connected between the driving voltage line PL and an organic light-emitting device OLED, and a data write transistor may be connected to the data line DL and the driving transistor, and may perform a switching operation of transmitting a data signal transmitted through the data line DL.

The compensation transistor may be turned on in response to a scan signal received through the scan line SL and connect the driving transistor to the organic light-emitting device OLED, thereby compensating for a threshold voltage of the driving transistor.

The initialization transistor may be turned on in response to the scan signal received through the scan line SL and transmit an initialization voltage to a gate electrode of the driving transistor, thereby initializing the gate electrode of the driving transistor. A scan line connected to the initialization transistor may be a separate scan line from a scan line connected to the compensation transistor.

An emission control transistor may be turned on in response to a light-emitting control signal received through a light-emitting control line, and as a result, a driving current may flow in the organic light-emitting device OLED.

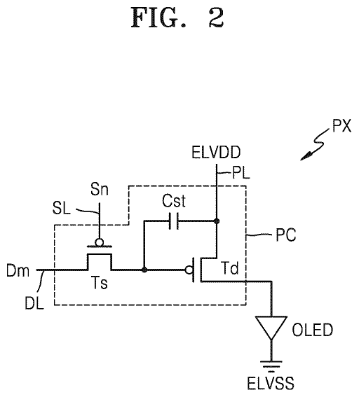

The organic light-emitting device OLED may include a pixel electrode (anode) 140 (see FIG. 3) and a counter electrode (cathode) 160 (see FIG. 3), and the counter electrode 160 may receive the common voltage ELVSS (see FIG. 2). The organic light-emitting device OLED may receive a driving current from the driving transistor and may display an image by emitting light.

In the following description, although an organic light-emitting display device is described as an example of the display device according to an embodiment, the display device according to one or more embodiments is not limited thereto. In another embodiment, the display device according to one or more embodiments may include display devices, such as an inorganic light-emitting display device (an inorganic light-emitting display or an inorganic EL display device), a quantum-dot light-emitting display device display device, and the like. For example, an emission layer of a display element in a display device may include an organic material or an inorganic material. Furthermore, the display device may include an emission layer and quantum dots located on a path of light emitted from the emission layer.

FIG. 2 is a schematic equivalent circuit diagram of a pixel of the display device of FIG. 1.

As illustrated in FIG. 2, each of the pixels PX may include the pixel circuit PC connected to the scan line SL and the data line DL, and the organic light-emitting diode OLED connected to the pixel circuit PC.

The pixel circuit PC may include a driving thin film transistor Td, a switching thin film transistor Ts, and a storage capacitor Cst. The switching thin film transistor Ts may be connected to the scan line SL and the data line DL, and transmit, in response to a scan signal Sn input through the scan line SL, a data signal Dm input through the data line DL to the driving thin film transistor Td.

The storage capacitor Cst may be connected to the switching thin film transistor Ts and the driving voltage line PL, and store a voltage corresponding to a difference between the voltage received from the switching thin film transistor Ts and a first power voltage (ELVDD or a driving voltage) supplied through the driving voltage line PL.

The driving thin film transistor Td may be connected to the driving voltage line PL and the storage capacitor Cst, and may control a driving current flowing in the organic light-emitting diode OLED through the driving voltage line PL corresponding to a value of the voltage stored in the storage capacitor Cst. The organic light-emitting diode OLED may emit light having a certain luminance by the driving current.

Although FIG. 2 illustrates that the pixel circuit PC includes two thin film transistors and a storage capacitor, the disclosure is not limited thereto. For example, pixel circuit PC may include two or more storage capacitors.

FIG. 3 is a schematic cross-sectional view of a part of the display device of FIG. 1.

The substrate 100 may include, as described above, areas corresponding to the display area DA and the peripheral area PA outside the display area DA. The substrate 100 may include various flexible or bendable materials. For example, the substrate 100 may include glass, metal, and/or polymer resin. Furthermore, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have various modifications, for example, a multilayer structure of two layers including polymer resin as above and a barrier layer arranged between the two layers and including an inorganic material, such as a silicon oxide, a silicon nitride, a silicon oxynitride, and/or the like.

The buffer layer 101 may be disposed on the substrate 100. The buffer layer 101 may prevent diffusion of impurities ions or infiltration of moisture or external air, and may serve as a barrier layer for planarizing a surface, and/or a blocking layer. The buffer layer 101 may include a silicon oxide, a silicon nitride, and/or a silicon oxynitride. Furthermore, the buffer layer 101 may control a heat supply speed during a crystallization process for forming a semiconductor layer 110, to uniformly crystalize the semiconductor layer 110.

The semiconductor layer 110 may be disposed on the buffer layer 101. The semiconductor layer 110 may be made of polysilicon, and include a channel region that is not doped with impurities, and a source region and a drain region formed in both sides of the channel region and doped with impurities. The impurities may vary depending on the type of a thin film transistor, and may be, for example, N-type impurities or P-type impurities.

A gate insulating film 102 may be disposed on the semiconductor layer 110. The gate insulating film 102 may be provided to secure insulation between the semiconductor layer 110 and a gate layer 120. The gate insulating film 102 may include a silicon oxide, a silicon nitride, a silicon oxynitride, and/or the like, and may be provided between the semiconductor layer 110 and the gate layer 120. Furthermore, the gate insulating film 102 may be formed on the entire surface of the substrate 100, and may have a structure in which contact holes are formed in preset portions. As such, an insulating film including an inorganic material may be formed through chemical vapor deposition (CVD) or atomic layer deposition (ALD). This applies to embodiments and modifications thereof described below in the same manner.

The gate layer 120 may be disposed on the gate insulating film 102. The gate layer 120 may be disposed at a position vertically overlapping the semiconductor layer 110, and may include at least one of a metal of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu). The gate layer 120 is described below in detail.

An interlayer insulating film 103 may be disposed on the gate layer 120. The interlayer insulating film 103 may cover the gate layer 120. The interlayer insulating film 103 may include an inorganic material. For example, the interlayer insulating film 103 may include a metal oxide or a metal nitride, and in detail, the inorganic material may include a silicon oxide (SiO₂), a silicon nitride (SiNₓ), a silicon oxynitride (SiON), an aluminum oxide (Al₂O₃), a titanium oxide (TiO₂), a tantalum oxide (Ta₂O₅), a hafnium oxide (HfO₂), a zinc oxide (ZrO₂), and/or the like. In some embodiments, the interlayer insulating film 103 may have a dual structure of SiOₓ/SiN_{y} or SiNₓ/SiO_{y}.

A conductive layer 130 may be disposed on the interlayer insulating film 103. The conductive layer 130 may serve as an electrode connected to the source/drain regions of the semiconductor layer 110 via a through-hole formed in the interlayer insulating film 103.

The conductive layer 130 may include one or more metals selected from among Al, Pt, Pd, Ag, Mg, Au, Ni, Nd, Ir, Cr, Li, Ca, Mo, Ti, W, and Cu. For example, the conductive layer 130 may include a Ti layer, an Al layer, and/or a Cu layer.

An organic insulating layer 104 may be disposed on the conductive layer 130. The organic insulating layer 104 that covers the conductive layer 130 and has an approximately flat upper surface may be an organic insulating layer serving as a planarized film. The organic insulating layer 104 may include an organic material, such as acryl, benzocyclobutene (BCB), hexamethyldisiloxane (HMDSO), or the like. The organic insulating layer 104 may be variously modified into, for example, a single layer, a multilayer, or the like.

Furthermore, although not illustrated in FIG. 3, various embodiments are possible, for example, an additional conductive layer and an additional insulating layer may be provided between the conductive layer 130 and the pixel electrode 140. In this state, the additional conductive layer may include the same material, and have the same layer structure, as the conductive layer described above. The additional insulating layer may include the same material, and have the same layer structure, as the organic insulating layer described above.

The pixel electrode 140 may be disposed on the organic insulating layer 104. The pixel electrode 140 may be connected to the conductive layer 130 via a contact hole formed in the organic insulating layer 104. A display element may be arranged on the pixel electrode 140. An organic light-emitting element OLED may be used as the display element. In other words, the organic light-emitting element OLED may be disposed, for example, on the pixel electrode 140. The pixel electrode 140 may include a transmissive conductive layer including a transmissive conductive oxide, such as ITO, In₂O₃, IZO, and/or the like, and a reflective layer including a metal, such as Al, Ag, and/or the like. For example, the pixel electrode 140 may have a three-layer structure of ITO/Ag/ITO.

A pixel defining layer 105 may be disposed on the organic insulating layer 104, and may cover an edge of the pixel electrode 140. In other words, the pixel defining layer 105 may cover the edge of the pixel electrode 140. The pixel defining layer 105 has an opening corresponding to a pixel, and the opening may be formed to expose at least a central portion of the pixel electrode 140.

The pixel defining layer 105 may include an organic material, such as polyimide, HMDSO, and/or the like. Furthermore, a spacer 80 may be disposed on the pixel defining layer 105. Although the spacer 80 is illustrated as being located in the peripheral area PA, the spacer 80 may be located in the display area DA. The spacer 80 may prevent the organic light-emitting diode OLED from being damaged due to sagging of a mask in a manufacturing process using the mask. The spacer 80 may include an organic insulating material, and may be formed in a single layer or multilayer.

An intermediate layer 150 and the counter electrode 160 may be located in an opening portion. The intermediate layer 150 may include a low-molecular weight or polymer material, and in case of including a low-molecular weight material, the intermediate layer 150 may include a hole injection layer (HIL), a hole transport layer (HTL), an emission layer (EML), an electron transport layer (ETL), an electron injection layer (EIL), and/or the like. In case that the intermediate layer 150 includes a polymer material, the intermediate layer 150 may generally have a structure including the HTL and the EML. The counter electrode 160 may include a transmissive conductive layer made of a transmissive conductive oxide, such as ITO, In₂O₃, IZO, and/or the like. The pixel electrode 140 may be used as an anode, and the counter electrode 160 may be used as a cathode. The above polarities of the electrodes may be reversely applied.

The structure of the intermediate layer 150 may not be limited to the above description, and may have various structures. For example, at least any one of the layers forming the intermediate layer 150 may be integrally formed with the counter electrode 160. In another embodiment, the intermediate layer 150 may include a layer patterned to corresponding to each of the pixel electrodes 140.

The counter electrode 160 may be arranged in the display area DA and on the entire surface of the display area DA. In other words, the counter electrode 160 may be integrally formed to cover multiple pixels. The counter electrode 160 may electrically contact a common power supply line 70 arranged in the peripheral area PA. In an embodiment, the counter electrode 160 may extend to a barrier rib 200.

A thin film encapsulation layer TFE may be arranged to entirely cover the display area DA and extend toward the peripheral area PA to thus cover at least a part of the peripheral area PA. The thin film encapsulation layer TFE may extend to the outside of the common power supply line 70.

The thin film encapsulation layer TFE may include a first inorganic encapsulation layer 310, a second inorganic encapsulation layer 330, and an organic encapsulation layer 320 provided therebetween. The first inorganic encapsulation layer 310 and the second inorganic encapsulation layer 330 may each include one or more inorganic materials of Al₂O₃, TiO₂, Ta₂O₅, HfO₂, ZrO₂, SiO₂, SiNₓ, and SiON. The first inorganic encapsulation layer 310 and the second inorganic encapsulation layer 330 may each be a single layer or multilayer including a material described above. The first inorganic encapsulation layer 310 and the second inorganic encapsulation layer 330 may include the same material, or different materials.

The first inorganic encapsulation layer 310 and the second inorganic encapsulation layer 330 may have different thicknesses. The thickness of the first inorganic encapsulation layer 310 may be greater than the thickness of the second inorganic encapsulation layer 330. In another embodiment, the thickness of the second inorganic encapsulation layer 330 may be greater than the thickness of the first inorganic encapsulation layer 310, or the thicknesses of the first inorganic encapsulation layer 310 and the second inorganic encapsulation layer 330 may be identical to each other.

The organic encapsulation layer 320 may include a monomer-based material or a polymer-based material. The polymer-based material may include acrylic resin, epoxy-based resin, polyimide, polyethylene, and/or the like. In an embodiment, the organic encapsulation layer 320 may include acrylate.

The barrier rib 200 may be arranged in the peripheral area PA on the substrate 100. In an embodiment, the barrier rib 200 may include a portion 230 of the organic insulating layer 104, a portion 220 of the pixel defining layer 105, and a portion 210 of the spacer 80, but the disclosure is not limited thereto. In some cases, the barrier rib 200 may include only the portion 230 of the organic insulating layer 104 or only the portion 220 of the pixel defining layer 105.

The barrier rib 200 may be arranged to surround the display area DA, and may prevent the organic encapsulation layer 320 of the thin film encapsulation layer TFE from overflowing to the outside of the substrate 100. Accordingly, the organic encapsulation layer 320 may be in contact with an inner surface of the barrier rib 200 facing the display area DA. In this state, the organic encapsulation layer 320 being in contact with the inner surface of the barrier rib 200 may be understood that the first inorganic encapsulation layer 310 is located between the organic encapsulation layer 320 and the barrier rib 200, and the organic encapsulation layer 320 contacts the first inorganic encapsulation layer 310. The first inorganic encapsulation layer 310 and the second inorganic encapsulation layer 330 may be disposed on the barrier rib 200, and may extend toward an edge of the substrate 100.

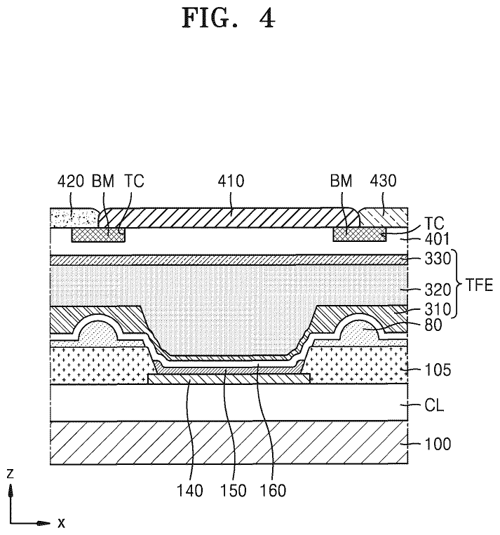

FIG. 4 is a schematic cross-sectional view of a part of the display device of FIG. 1.

As illustrated in FIG. 4, the display device according to an embodiment may include the substrate 100, a circuit layer CL, the pixel electrode 140, the intermediate layer 150, the counter electrode 160, and the thin film encapsulation layer TFE, and further include an insulating layer 401, a light blocking material layer BM, and color filter layers 410, 420, and 430 disposed on the thin film encapsulation layer TFE.

The circuit layer CL may be disposed on the substrate 100, and may be defined to be a term to describe components including the buffer layer 101, the semiconductor layer 110, the gate insulating film 102, the gate layer 120, the interlayer insulating film 103, the conductive layer 130, the organic insulating layer 104, and the like, which are described above in FIG. 3, as one name, for convenience of explanation. In other words, in the specification, the circuit layer CL may include constituent elements located between the substrate 100 and the pixel electrode 140 in FIG. 3.

As illustrated in FIG. 4, the display device according to an embodiment may include the substrate 100, the pixel electrodes 140 disposed on the substrate 100, the emission layer EML (or the intermediate layer 150) disposed on each of the pixel electrodes 140, the counter electrode 160 disposed on the emission layer EML and integrally formed to correspond to the pixel electrodes 140, the insulating layer 401 disposed on the counter electrode 160 and including a trench TC corresponding to an area between the pixel electrodes 140, the light blocking material layer BM disposed in the trench TC, and the first, second, and third color filter layers 410, 420, and 430 disposed on the insulating layer 401 and selectively transmitting light of a specific wavelength band.

In this state, the thickness of the light blocking material layer BM may be the same as the depth of the trench TC, or an upper surface outside the trench TC and the upper surface of the light blocking material layer BM may form a continuous surface. The trench TC may be formed by a process of etching the insulating layer 401 using a mask.

The light blocking material layer BM, as a black matrix, may include various materials capable of absorbing at least part of light. For example, the light blocking material layer BM may include at least one of carbon black, graphite, a chromium-based material, dye, a metal-based reflective film, and a light absorbing film. The light blocking material layer BM may not only block or prevent the reflection of external light, but also prevent internal reflection of light generated from the display element.

The thickness of the light blocking material layer BM may be several micrometers or less, and may be about 1.4 μm or more and about 1.5 μm or less. In case that the thickness of the light blocking material layer BM is less than about 1.4 μm or greater than about 1.5 μm, a light blocking rate may be lowered. Accordingly, the depth of the trench TC may be several micrometers or less, and may be about 1.4 μm or more and about 1.5 μm or less.

The light blocking material layer BM may be located above the pixel defining layer 105. In other words, the light blocking material layer BM may not be located above a pixel opening that exposes the pixel electrode 140. As the light blocking material layer BM is located in the trench TC, the positional characteristic of the light blocking material layer BM may be the same as the positional characteristic of the trench TC.

The light blocking material layer BM may be located above the spacer 80. As the light blocking material layer BM is disposed on the spacer 80, in a process of forming constituent elements, such as the color filters 410, 420, and 430 and the like disposed on the light blocking material layer BM, impact or stress applied to other elements during using a mask may be reduced.

When viewed from a direction perpendicular to the substrate 100 (e.g., in plan view), the light blocking material layer BM or the trench TC may not overlap the pixel opening. In other words, when viewed from the direction perpendicular to the substrate 100, the light blocking material layer BM or the trench TC may overlap the pixel defining layer 105, or overlap a spacer located on the pixel defining layer 105. When viewed from the direction perpendicular to the substrate 100, the light blocking material layer BM or the trench TC may be apart a certain distance from an edge of the pixel opening. When viewed from the direction perpendicular to the substrate 100, the light blocking material layer BM or the trench TC is located adjacent to the pixel opening, the light blocking material layer BM may block part of light (internal light) generated in the display element, thereby causing degradation of the quality of an image of the display device.

Furthermore, when viewed from the direction perpendicular to the substrate 100, the spacer 80 may be located in the trench TC, the trench TC may overlap the pixel defining layer 105, and the width of the trench TC may be less than the distance between the pixel openings.

The insulating layer 401 may be located on the second inorganic encapsulation layer 330 of the thin film encapsulation layer TFE described above, and may include the same material as the second inorganic encapsulation layer 330. Accordingly, it may be difficult to discriminate the insulating layer 401 from the second inorganic encapsulation layer 330, on an enlarged image capturing the insulating layer 401 and the second inorganic encapsulation layer 330.

The insulating layer 401 may be disposed on the second inorganic encapsulation layer 330. The insulating layer 401 may be an inorganic insulating layer including one or more inorganic materials, such as Al₂O₃, TiO₂, Ta₂O₅, HfO₂, ZrO₂, SiO₂, SiNₓ, and SiON. The insulating layer 401 may be a single layer or multilayer including the material described above. The insulating layer 401 may be an inorganic insulating layer constituting a touch unit described below.

In case that the insulating layer 401 is formed on the second inorganic encapsulation layer 330, by deducting the depth of the trench TC from the thickness obtained by summing the thickness of the insulating layer 401 and the thickness of the second inorganic encapsulation layer 330, the thickness may be about 0.6 μm or more and about 0.8 μm or less, particularly about 0.7 μm. In case that the insulating layer 401 is formed on the second inorganic encapsulation layer 330, the thickness of the second inorganic encapsulation layer 330 may be less than about 0.6 μm. Accordingly, the depth of the trench TC may be greater than the thickness of the second inorganic encapsulation layer 330, and the thickness of the insulating layer 401 including the trench TC may be greater than the thickness of the second inorganic encapsulation layer 330.

In some cases, the insulating layer 401 may be understood as a part of the second inorganic encapsulation layer 330. In other words, in a structure not including a touch unit, the insulating layer 401 that is additional is not necessary, the thickness of the second inorganic encapsulation layer 330 may be increased, and the trench TC may be formed in the second inorganic encapsulation layer 330.

The thickness of the second inorganic encapsulation layer 330 may be increased to secure the depth of the trench TC. The depth of the trench TC may be several micrometers or less, like the thickness of the light blocking material layer BM, and particularly, about 1.4 μm or more and about 1.5 μm or less. Accordingly, the thickness of the second inorganic encapsulation layer 330 may be greater than about 1.4 μm or about 1.5 μm.

In case that the insulating layer 401 is a part of the second inorganic encapsulation layer 330, the thickness obtained by deducting the depth of the trench TC from the thickness of the second inorganic encapsulation layer 330 may be about 0.6 μm or more and about 0.8 μm or less, particularly about 0.7 μm. In the thickness of the second inorganic encapsulation layer 330, in case that the thickness other than the depth of the trench TC is less than about 0.6 μm, it may be difficult to block external moisture or oxygen. In case that the thickness other than the depth of the trench TC is greater than about 0.8 μm, it may be problematic that the entire thickness of the second inorganic encapsulation layer 330 is excessively large.

In other words, there is a need to sufficiently protect the display element in an addition process of forming the first, second, and third color filter layers 410, 420, and 430, and the like after forming the insulating layer 401, and a thickness needed to perform the function of the second inorganic encapsulation layer 330 on the organic encapsulation layer 320 of the thin film encapsulation layer TFE may be about 0.6 μm or more and about 0.8 μm or less, particularly about 0.7 μm.

The color filter layers 410, 420, and 430 may be disposed on the insulating layer 401. The color filter layers 410, 420, and 430 may be components to selectively transmit light of a specific wavelength band, and the specific wavelength band that the first, second, and third color filter layers 410, 420, and 430 transmit may correspond to a wavelength band of the light emitted from the display element located below the first, second, and third color filter layers 410, 420, and 430 corresponding thereto.

In detail, the first, second, and third color filter layers 410, 420, and 430 may include a first color filter layer 410 for transmitting light of a first wavelength band, a second color filter layer 420 for transmitting light of a second wavelength band different from the first wavelength band, and a third color filter layer 430 for transmitting light of a third wavelength band different from the first wavelength band and the second wavelength band. In an example, the first wavelength band to the third wavelength band may be a wavelength band corresponding to one of the three primary colors of light known as RGB.

When viewed from the direction perpendicular to the substrate 100, an edge of the first color filter layer 410 may overlap the light blocking material layer BM. Furthermore, when viewed from the direction perpendicular to the substrate 100, a side of an edge of the second color filter layer 420 may be adjacent to a side of the edge of the first color filter layer 410. Likewise, when viewed from the direction perpendicular to the substrate 100, a side of an edge of the third color filter layer 430 may be adjacent to another side of the edge of the first color filter layer 410.

In other words, when viewed from the direction perpendicular to the substrate 100, the second color filter layer 420 may be adjacent to the first color filter layer 410, and the third color filter layer 430 may be adjacent to the first color filter layer 410.

When viewed from the direction perpendicular to the substrate 100, the edge of the second color filter layer 420 and the edge of the third color filter layer 430 may also overlap the light blocking material layer BM. In this state, overlapping the light blocking material layer BM may have the same meaning as overlapping the trench TC.

Although not illustrated in FIG. 4, while the depth of the trench TC is constant, the thickness of the light blocking material layer BM may be changed. The thickness of the light blocking material layer BM may be greater than the depth of the trench TC. In case that the thickness of the light blocking material layer BM is greater than the depth of the trench TC, the edges of the first, second, and third color filter layers 410, 420, and 430 may be apart from the insulating layer 401 as much as the height that a part of the light blocking material layer BM protrudes than the trench TC.

In other words, the edges of the first, second, and third color filter layers 410, 420, and 430 may cover at least part of an area in which a part of the light blocking material layer BM protrudes from the trench TC. As the edges of the first, second, and third color filter layers 410, 420, and 430 rises, a curvature may be formed in the upper surfaces of the first, second, and third color filter layers 410, 420, and 430, and the upper surfaces of the first, second, and third color filter layers 410, 420, and 430 may be curved in a direction toward the substrate 100. As such, the curvatures of the upper surfaces of the first, second, and third color filter layers 410, 420, and 430 may be adjusted through the adjustment of the thickness of the light blocking material layer BM.

Although not illustrated in FIG. 4, the part of the light blocking material layer BM may not be disposed in the trench TC. In other words, the trench TC may not exist between some pixel electrodes. The light blocking material layer BM may be disposed on the insulating layer 401, and the edges of the first, second, and third color filter layers 410, 420, and 430 may rise as high as the depth of the trench TC. As such, the curvatures of the upper surfaces of the first, second, and third color filter layers 410, 420, and 430 may be adjusted through the arrangement of the trench TC.

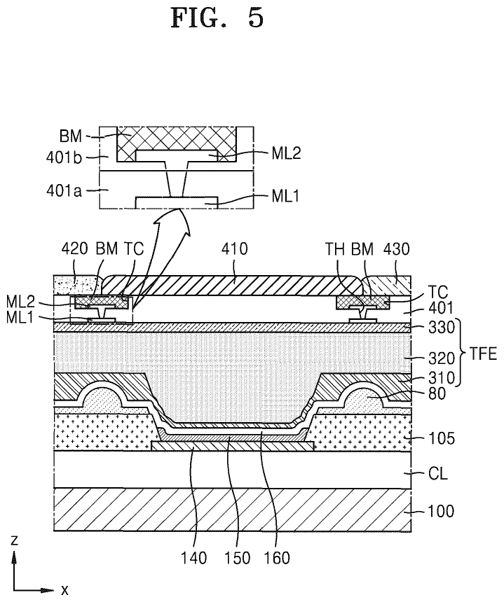

FIG. 5 is a schematic cross-sectional view of the vicinity of a color filter layer of the display device of FIG. 1. In the descriptions of FIG. 5, the contents that are the same as or redundant to those of the descriptions presented above may be omitted.

As illustrated in FIG. 5, the insulating layer 401 may constitute a touch unit. The touch unit may include sensing electrodes ML1 and ML2, a signal line (not shown) connected to the sensing electrodes ML1 and ML2, and the insulating layer 401. The touch unit may sense an external input by, for example, a capacitance method. In one or more embodiments, a touch unit operation method is not particularly limited, and the external input may be sensed by an electromagnetic induction method or a pressure sensing method.

The insulating layer 401 may have a multilayer structure including a first inorganic insulating layer 401a and a second inorganic insulating layer 401b on the first inorganic insulating layer 401a. In this state, the second inorganic insulating layer 401b may include the trench TC described above. Furthermore, the touch unit may include a sensing electrode, and the sensing electrode may include a first metal electrode ML1 and a second metal electrode ML2.

The first metal electrode ML1 may be disposed on the second inorganic encapsulation layer 330, and may be covered by the insulating layer 401. In detail, the first metal electrode ML1 may be covered by the first inorganic insulating layer 401a. The second metal electrode ML2 may be disposed on a lower surface of the trench TC to be disposed within the trench TC, and may be connected to the first metal electrode ML1 via a through-hole TH formed in the insulating layer 401. In case that the second metal electrode ML2 is disposed in the trench TC, the light blocking material layer BM may cover the second metal electrode ML2.

The stack structure and material of the sensing electrode, such as the first metal electrode ML1 and the second metal electrode ML2, may be determined considering sensing sensitivity. The first metal electrode ML1 and the second metal electrode ML2 may each include at least one of molybdenum, silver, titanium, copper, aluminum, and an alloy thereof. The first metal electrode ML1 and the second metal electrode ML2 may each have a three-layer structure, for example, a Ti/Al/Ti structure. The first metal electrode ML1 and the second metal electrode ML2 may have a mesh structure, when viewed from the direction perpendicular to the substrate 100.

The stack structure and material of the sensing electrodes may be determined considering the sensing sensitivity. An RC delay may affect the sensing sensitivity, the sensing electrodes including a metal layer may have a resistance smaller than a transparent conductive layer, and thus, an RC value may be decreased. Accordingly, a charging time of a capacitor defined between the sensing electrodes is decreased. The capacitance may be formed between the sensing electrodes and the counter electrode 160.

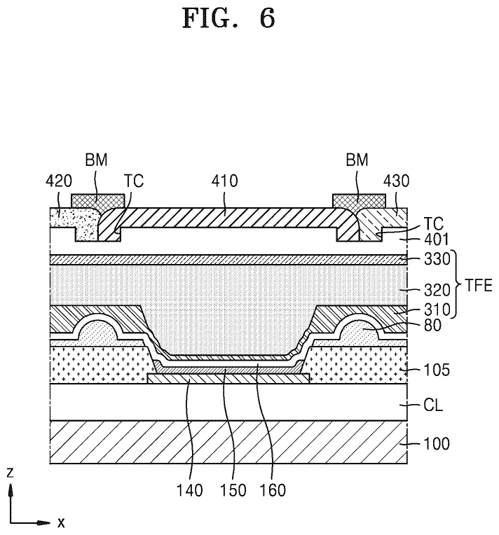

FIG. 6 is a schematic cross-sectional view of the vicinity of a color filter layer of a display device according to an embodiment. In the descriptions of FIG. 6, the contents that are the same as or redundant to those of the descriptions presented above may be omitted.

As illustrated in FIG. 6, the display device may include the substrate 100, the pixel electrodes 140 disposed above the substrate 100, the emission layer EML (or the intermediate layer 150) disposed on each of the pixel electrodes 140, the counter electrode 160 disposed on the emission layer EML and integrally formed to correspond to the pixel electrodes 140, the insulating layer 401 above the counter electrode 160 and including the trench TC corresponding thereto between the pixel electrodes 140, and the first color filter layer 410 disposed on the insulating layer 401, transmitting light of a first wavelength band, and having an edge disposed within the trench TC.

The display device may further include the second color filter layer 420 disposed on the insulating layer 401, transmitting light of a second wavelength band different from the first wavelength band, being adjacent to the first color filter layer 410, and having an edge disposed within the trench TC. In other words, the first color filter layer 410 and the second color filter layer 420 may be adjacent to each other, a side of the edge of the first color filter layer 410 and a side of the edge of the second color filter layer 420 may be in direct contact with each other in the trench TC.

The display device may further include the light blocking material layer BM disposed on an interface where the edge of the first color filter layer 410 meets the edge of the second color filter layer 420. Furthermore, the light blocking material layer BM may be disposed on an interface where the edge of the first color filter layer 410 meets the edge of the third color filter layer 430. In other words, unlike FIGS. 4 and 5, the light blocking material layer BM may be disposed on the first, second, and third color filter layers 410, 420, and 430, and on the interfaces where the first, second, and third color filter layers 410, 420, and 430 are in contact with each other.

As such, as the light blocking material layer BM is disposed on the first, second, and third color filter layers 410, 420, and 430, the formation of the curvatures of the upper surfaces of the first, second, and third color filter layers 410, 420, and 430 due to the thickness of the light blocking material layer BM may be prevented.

The display device may further include the third color filter layer 430 disposed on the insulating layer 401, transmitting light of a third wavelength band different from the first wavelength band and the second wavelength band, being adjacent to the first color filter layer 410, and having an edge located in the trench TC. In other words, the first color filter layer 410 and the third color filter layer 430 may be adjacent to each other, and another side of the edge of the first color filter layer 410 and a side of the edge of the third color filter layer 430 may be in direct contact with each other in the trench TC.

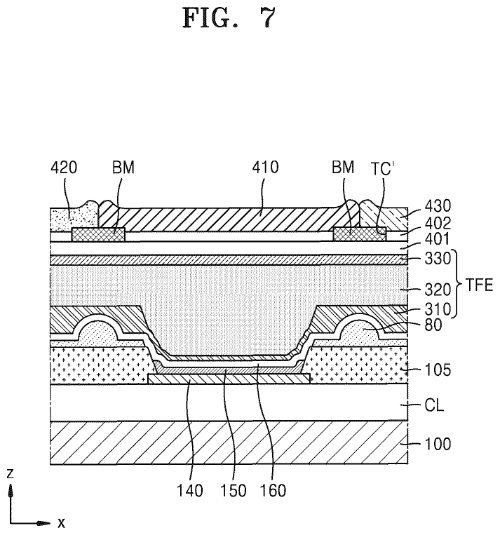

FIG. 7 is a schematic cross-sectional view of the vicinity of a color filter layer of the display device of FIG. 1. In the descriptions of FIG. 7, the contents that are the same as or redundant to those of the descriptions presented above may be omitted.

As illustrated in FIG. 7, the display device may further include an additional organic insulating layer 402 on the insulating layer 401. Unlike the trench TC of the display devices described above, in the display device of FIG. 7, a trench TC′ may not be formed in the insulating layer 401, an opening for exposing the insulating layer 401 may be formed in the additional organic insulating layer 402. In this state, the additional organic insulating layer 402, unlike the insulating layer 401, may include an organic material, such as acryl, BCB, HMDSO, or the like. The light blocking material layer BM may be located in the opening formed in the additional organic insulating layer 402. The additional organic insulating layer 402 may use an organic material that may be formed by a low temperature process, which is to prevent damage occurring due to high heat to other constituent elements that are previously formed.

In other words, the display devices of FIGS. 4 to 6 may be manufactured by a process of forming the trench TC in the insulating layer 401, and forming the light blocking material layer BM in the trench TC that may be formed, whereas, reversely, the display device of FIG. 7 may be formed by forming the light blocking material layer BM on the insulating layer 401 in a preset shape, and patterning the additional organic insulating layer 402 between the light blocking material layers BM. The additional organic insulating layer 402 may include multiple additional sub-organic insulating layers corresponding to multiple pixel openings. In other words, each of multiple additional sub-organic insulating layers may correspond to any one of the first color filter layer 410 to the third color filter layer 430.

The first color filter layer 410 to the third color filter layer 430 may be disposed on the additional organic insulating layer 402, and the edges of the first color filter layer 410 to the third color filter layer 430 are disposed on the light blocking material layer BM and may be formed along the light blocking material layer BM. Furthermore, a side of the edge of the first color filter layer 410 and a side of the edge of the second color filter layer 420 may be adjacent to each other on the light blocking material layer BM, and another side of the edge of the first color filter layer 410 may be adjacent to a side of the edge of the third color filter layer 430 on the light blocking material layer BM.

When viewed from the direction perpendicular to the substrate 100, the pixel opening may be disposed in each of multiple additional insulating layers 402. Furthermore, when viewed from the direction perpendicular to the substrate 100, one of the additional insulating layers 402 may be disposed in the first color filter layer 410.

Furthermore, as described above, the insulating layer 401 may be substituted by the second inorganic encapsulation layer 330.

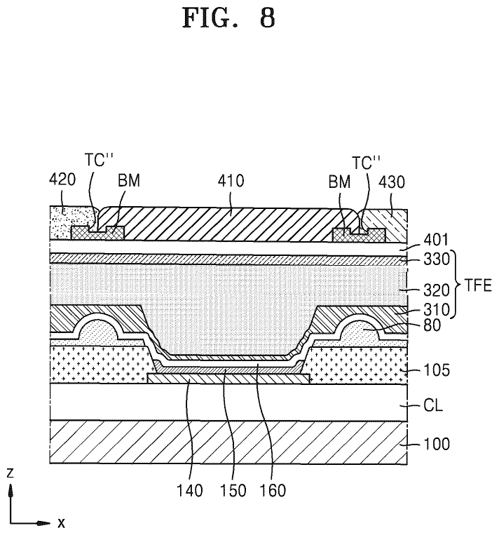

FIG. 8 is a schematic cross-sectional view of the vicinity of a color filter layer of the display device of FIG. 1. In the descriptions of FIG. 8, the contents that are the same as or redundant to those of the descriptions presented above may be omitted.

Unlike the trenches TC and TC′ of the display devices described above, in the display device of FIG. 8, no trench may be formed in the insulating layer 401, and a trench TC″ may be formed in the light blocking material layer BM. In other words, the light blocking material layer BM includes the trench TC″, and the edge of the first color filter layer 410 may be located in the trench TC″.

Furthermore, the edge of the second color filter layer 420 adjacent to the first color filter layer 410 may also be located in the trench TC″. In the trench TC″ in the light blocking material layer BM, a side of the edge of the first color filter layer 410 and a side of the edge of the second color filter layer 420 may be in close contact with each other.

Furthermore, the edge of the third color filter 430 adjacent to the first color filter layer 410 may also be located in the trench TC″. In the trench TC″ in the light blocking material layer BM, a side of the edge of the first color filter layer 410 and a side of the edge of the third color filter layer 430 may be in close contact with each other.

According to one or more embodiments configured as above, the display device, in which the scattering reflection of external light by a color filter is reduced, may be implemented. The scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope of the disclosure.

What is claimed is:

1. A display device comprising:
a plurality of pixel electrodes disposed on a substrate;
an emission layer disposed on each of the plurality of pixel electrodes;
a counter electrode disposed on the emission layer to correspond to the plurality of pixel electrodes;
an insulating layer disposed on the counter electrode and including a trench corresponding to an area between the plurality of pixel electrodes;
a light blocking material layer disposed in the trench; and
a color filter layer disposed on the insulating layer and selectively transmitting light of a specific wavelength band.

2. The display device of claim 1, wherein a thickness of the light blocking material layer and a depth of the trench are same.

3. The display device of claim 1, wherein an upper surface outside the trench and an upper surface of the light blocking material layer form a continuous surface.

4. The display device of claim 1, further comprising:
a thin film encapsulation layer disposed between the counter electrode and the insulating layer, and including a first inorganic encapsulation layer;
a second inorganic encapsulation layer disposed on the first inorganic encapsulation layer; and
an organic encapsulation layer disposed between the first inorganic encapsulation layer and the second inorganic encapsulation layer, wherein
the second inorganic encapsulation layer and the insulating layer include a same material.

5. The display device of claim 4, wherein a thickness of the insulating layer is greater than a thickness of the second inorganic encapsulation layer.

6. The display device of claim 4, wherein a depth of the trench is greater than a thickness of the second inorganic encapsulation layer.

7. The display device of claim 4, further comprising:
a first metal electrode disposed on the second inorganic encapsulation layer and covered by the insulating layer; and
a second metal electrode disposed on a lower surface of the trench to be disposed in the trench, and connected to the second metal electrode via a through-hole formed in the insulating layer.

8. The display device of claim 7, wherein the light blocking material layer covers the second metal electrode.

9. The display device of claim 1, wherein a depth of the trench is about 1.4 μm or more and about 1.5 μm or less.

10. The display device of claim 1, wherein
the color filter layer includes a first color filter layer that transmits light of a first wavelength band, and
when viewed from a direction perpendicular to the substrate, an area of the first pixel opening is less than an area of the first color filter layer.

11. The display device of claim 10, wherein the light blocking material layer is disposed adjacent to an edge of the first color filter layer.

12. The display device of claim 1, further comprising:
a pixel defining layer disposed on the substrate and including a plurality of pixel openings that expose a central portion of each of the plurality of pixel electrodes disposed on the substrate; and
a spacer disposed on the pixel defining layer.

13. The display device of claim 12, wherein, when viewed from a direction perpendicular to the substrate, the spacer is disposed in the trench.

14. The display device of claim 12, wherein, when viewed from a direction perpendicular to the substrate, the trench overlaps the pixel defining layer.

15. The display device of claim 12, wherein, when viewed from a direction perpendicular to the substrate, a width of the trench is less than a distance between the pixel openings.

16. A display device comprising:
a plurality of pixel electrodes disposed on a substrate;
an emission layer disposed on each of the plurality of pixel electrodes;
a counter electrode disposed on the emission layer to correspond to the plurality of pixel electrodes;
an insulating layer disposed on the counter electrode and including a trench corresponding to an area between the plurality of pixel electrodes; and
a first color filter layer disposed on the insulating layer and transmitting light of a first wavelength band, an edge of the first color filter layer being disposed in the trench.

17. The display device of claim 16, further comprising a second color filter layer disposed on the insulating layer to be adjacent to the first color filter layer, transmitting light of a second wavelength band that is different from the first wavelength band, and including an edge disposed in the trench.

18. The display device of claim 17, further comprising a light blocking material layer disposed on an interface where the edge of the first color filter layer meets an edge of the second color filter layer.

19. The display device of claim 18, further comprising a third color filter layer disposed on the insulating layer to be adjacent to the first color filter layer, transmitting light of a third wavelength band that is different from the first wavelength band and the second wavelength band, and including an edge disposed in the trench.

20. The display device of claim 19, wherein the light blocking material layer is disposed on an interface where the edge of the first color filter layer meets an edge of the third color filter layer.
